(19) United States
(12) Patent Application Publication
(10) Pub. No.: US 2004/0124933 A1
(43) Pub. Date: Jul. 1, 2004

(54) Voltage controlled oscillator using photonic bandgap structure and feedforward circuit and method thereof

(76) Inventors: Byung-Su Kang, Daejon (KR); Young-Wan Kim, Daejon (KR); Nae-Soo Kim, Daejon (KR); Chulhun Seo, Seoul (KR); Uktae Chang, Seoul (KR)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/734,839

(22) Filed: Dec. 11, 2003

(30) Foreign Application Priority Data
Dec. 24, 2002 (KR) 2002-83591

(51) Int. Cl. H03B 5/18

(52) U.S. Cl. 331/107 SL

(57) ABSTRACT

A voltage controlled oscillator using a resonator having a photonic bandgap structure and a feedforward circuit is disclosed. The voltage controlled oscillator includes a resonation unit for resonating an oscillated signal by using a resonator having the photonic bandgap structure in order to increase a quality factor and an oscillation unit for controlling a phase of the oscillated signal by using the feedforward circuit in order to reduce phase noise. The present invention can reduce phase noise and increase efficiency of integration by using the photonic bandgap structure of a resonator and the feedforward circuit is used for maintaining high Q factor.

### FIELD OF THE INVENTION

The present invention relates to a voltage controlled oscillator using photonic a bandgap structure and a feedforward circuit and method thereof; and, more particularly, to a voltage controlled oscillator for reducing a phase noise by using a resonator having a photonic bandgap structure in order to increase a quality (Q) factor of a transmission line and using a feedforward circuit in order to increase linearity by eliminating noise at an output ports.

### DESCRIPTION OF RELATED ARTS

A conventional receiver of a communication system extracts a desired signal by generating a signal having identical frequency to a received signal and combining the generated signal and the received signal. For generating the signal having identical frequency, the conventional receiver generally uses a voltage controlled oscillator VCO.

The conventional voltage controlled oscillator VCO is a device converting a frequency according to variation of an applied voltage. For converting the frequency, the conventional voltage controlled oscillator is implemented by using an element having a variable characteristic according to variation of voltage, e.g., a varactor diode.

The conventional voltage controlled oscillator includes a LC (liquid crystal) circuit having an inductor and varactor diode.

An output signal of the LC circuit is applied to a resonator through a couple capacitors. The couple capacitor causes to increase loss in a high frequency bandwidth and as a result, the quality Q factor is decreased. Therefore, the phase noise is increased and characteristics of signal are also decreased.

### SUMMARY OF THE INVENTION

It is, therefore, an object of the present invention to provide a voltage controlled oscillator for reducing a phase noise by using a resonator having a photonic bandgap structure in order to increase a quality (Q) factor of a transmission line and using a feedforward circuit in order to increase linearity by eliminating noise at an output ports.

In accordance with an aspect of the present invention, there is provided a voltage controlled oscillator using a resonator having a photonic bandgap structure and a feedforward circuit, the voltage controlled oscillator including: a resonation unit for resonating an oscillated signal by using a resonator having the photonic bandgap structure in order to increase a quality factor; and oscillation unit for controlling a phase of the oscillated signal by using the feedforward circuit in order to reduce phase noise.

In accordance with an aspect of the present invention, there is also provided a method of operations of the voltage controlled oscillator by using a phonic bandgap structure and a feedforward circuit, the method including the steps of: a) resonating an oscillated signal by using a resonator having the photonic bandgap structure in order to increase a quality factor; and b) controlling a phase of the oscillated signal by using the feedforward circuit in order to reduce phase noise.

### BRIEF DESCRIPTION OF THE DRAWING(S)

The above and other objects and features of the present invention will become apparent from the following description of the preferred embodiments given in conjunction with the accompanying drawings, in which:

FIG. 1 is a circuit diagram illustrating a feedforward circuit in accordance with a preferred embodiment of the present invention;

FIG. 2 is a voltage controlled oscillator using a resonator having a photonic bandgap structure and a feedforward circuit in accordance with a preferred embodiment of the present invention;

FIG. 3 is a conceptual view for explaining operations of a feedforward circuit used in the present invention;

FIG. 4 is a diagram showing a photonic bandgap used in a resonator in accordance with a preferred embodiment of the present invention;

FIG. 5 is a layout depicting a conventional voltage controlled oscillator using a resonator having a photonic bandgap structure;

FIG. 6 is a layout depicting a voltage controlled oscillator using a resonator having a photonic bandgap structure and a feedforward circuit in accordance with a preferred embodiment of the present invention; and

FIG. 7 is a diagram illustrating a voltage controlled oscillator using a photonic bandgap structure and a feedforward circuit in accordance with a preferred embodiment of the present invention.

### DETAILED DESCRIPTION OF THE INVENTION

Other objects and aspects of the invention will become apparent from the following description of the embodiments with reference to the accompanying drawings, which is set forth hereinafter.

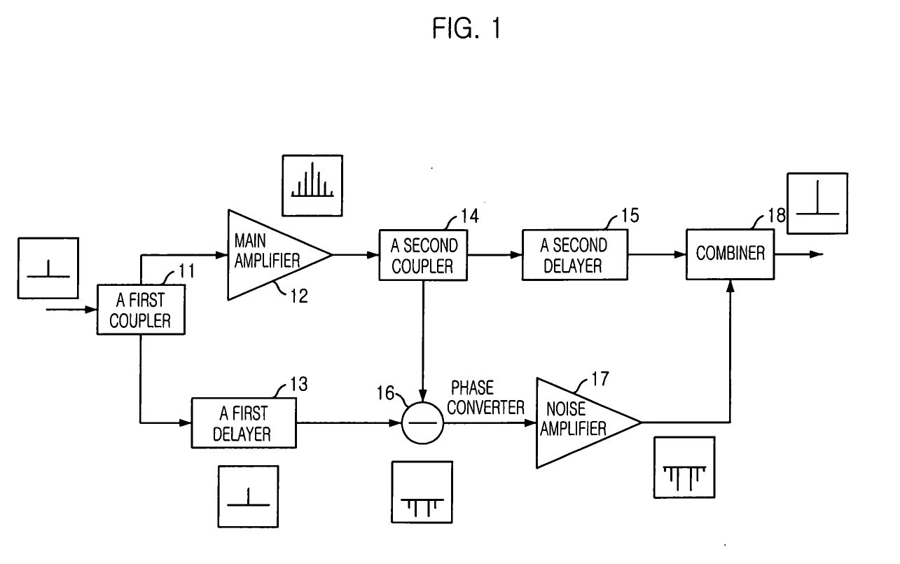

FIG. 1 is a circuit diagram illustrating a feedforward circuit in accordance with a preferred embodiment of the present invention.

The feedforward circuit shown in FIG. 1 excellently performs to linearize an output of the power amplifier by controlling a size of phase and eliminating noise elements at the output port after copying an input signal.

Referring to FIG. 1, the feedforward circuit includes a first coupler 11, a main amplifier 12, a first delayer 13, a second coupler 14, a second delayer 15, a phase converter 16, an noise amplifier 17 and a combiner 18.

Hereinafter, operations of the feedforward circuit in FIG. 1 are explained in detail.

When a signal is inputted, the first coupler 11 copies the input signal in order to generate a copied signal and transmits the copied signal to the main amplifier 12 and the first delayer 13. The main amplifier 12 amplifies the copied signal in order to generate an amplified signal and transmits the amplified signal to the second coupler 14. The second coupler 14 generates a second copied signal by copying the amplified signal. The second copied signal is transmitted to the second delayer 15. Also, the second copied signal is transmitted to the phase converter 16 and it is reversed at the phase converter 16 in order to generate a reversed signal. The reversed signal is combined with a first delayed signal from the first delayer 13 at the phase converter. The combined signal is transmitted to the noise amplifier 17. The combined signal is amplified and transmitted to the combiner 18. The second delayer 15 received the second copied signal from the second coupler 14 and generates a second delayed signal. The second delayed signal is transmitted to the combiner 18. The combiner 18 combines the second delayed signal and the combined signal and finally, an amplified signal is generated by eliminating the noise elements.

The first delayer 13 delays to transmit the copied signal to the phase converter 16 as long as the copied signal passes the main amplifier 12 and the second coupler 14. Also, the second delayer 15 delays to transmit the second copied signal to the combiner 18 as long as the second copied signal passes the phase converter 16 and the noise amplifier 17.

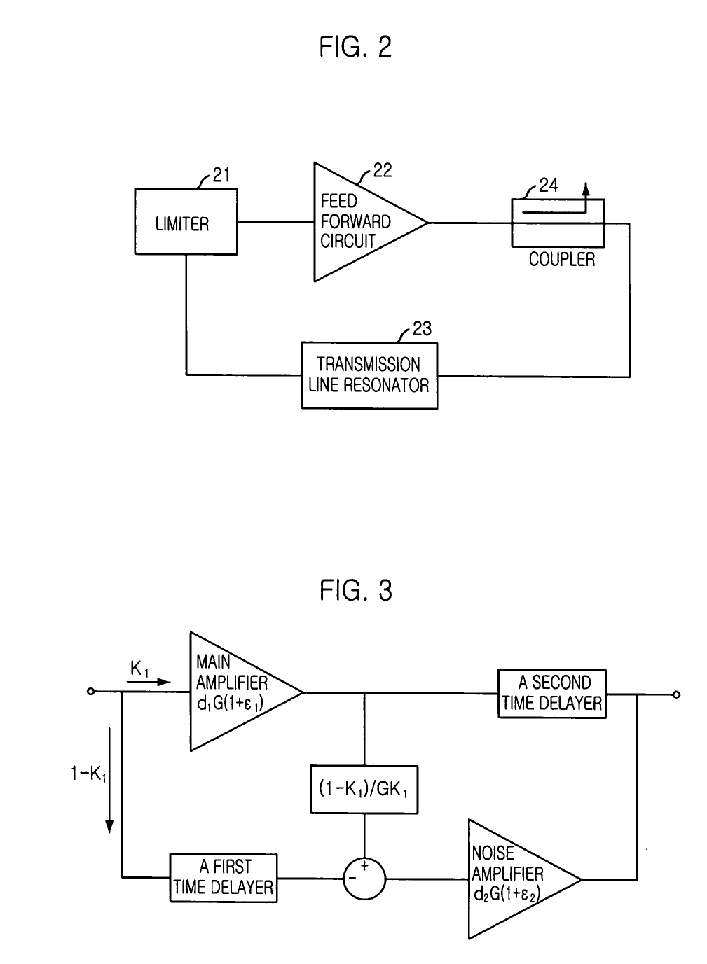

FIG. 2 is a voltage controlled oscillator using a resonator having a photonic bandgap structure and a feedforward circuit in accordance with a preferred embodiment of the present invention.

Referring to FIG. 2, the voltage controlled oscillator includes a limiter 21 for limiting a size of input signal, a feedforward circuit 22 for improving linearity by copying an input signal in order to control a size of phase and eliminating the noise element, a transmission line resonator 23 and a coupler 24 for generating an output signal. Detailed operations of each elements of the voltage controlled oscillator will be explained in later.

FIG. 3 is a conceptual view for explaining operations of a feedforward circuit used in the present invention.

Referring to FIG. 3, (1+ε₁)of the main amplifier and (1+ε₂)of the noise amplifier means a flicker noise and an ideal gain is expressed (1−K₁)/GK. The flicker noise is modulated noise having constant value and it's sideband noise is varied according to a size of carrier wave.

A current transfer in the feedforward circuit can be expressed as following equation 1.

P_{T}=K₁G(1−K₁)[1+ε₁(1−σ₂)+ε₂(1−σ₁)] Eq. 1

In the Eq. 1, if a suppression of each loop is 23 dB and flicker noise levels of noise amplifier and main amplifier are identical, then the suppression of loop can be reduced 20 dB. However, it cannot be reduced less than noise level of the feedforward circuit.

The noise lever of the feedforward circuit can be expressed as following equation 2.

$${F}_{ff} = \frac{{F}_{error}}{{L}_{input\_coupler} {L}_{delay\_line} {L}_{error\_emp \_input \_coupler}} \qquad Eq . 2$$

If a phase noise of the feedforward circuit is limited by thermal noise, the phase noise of the voltage controlled oscillator can be expressed as following equation 3.

$${L}_{fm} = \frac{FkT}{8 {{Q}_{0}^{2} ( \frac{{Q}_{L}}{{Q}_{0}} )}^{2} {( 1 - \frac{{Q}_{L}}{{Q}_{0}} )}^{2} {P}_{avo}} {( \frac{{f}_{0}}{Δ f} )}^{2} \qquad Eq . 3$$

F: amplifier noise figure

k: Boltzmann constant

T: temperature

Q₀: unloaded Q of resonator

Qₗ: loaded Q of resonator

Pₐᵥₒ: power abailable from the output of amplifier

fₐ: center frequency

Δf: carrier offset frequency

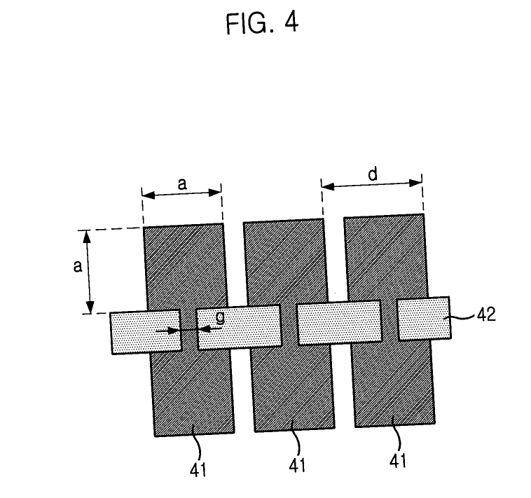

FIG. 4 is a diagram showing a photonic bandgap used in a resonator in accordance with a preferred embodiment of the present invention.

The photonic bandgap structure of the present invention is formed by carving a predetermined shape on a ground side of the transmission line in order to maximize coupling. That is, it is a structure improving the quality Q factor of the transmission line. For integration of high frequency bandwidth, a microstrip resonator or LC resonator are used. The LC resonator has a narrow bandwidth characteristic so the microstrip resonator is generally used. However, the microstrip resonator has disadvantages of high phase noise. The photonic bandgap structure is used for improving high phase noise of the microstrip resonator.

The photonic bandgap structure includes a rear side of circuit board 41 representing a carved ground side and a signal line 42. Inhere, ‘a’ is denoted as a width of the photonic bandgap, ‘g’ is denoted as an interval between signal lines and ‘d’ is a period.

FIG. 6 is a layout depicting a voltage controlled oscillator using a resonator having a photonic bandgap structure and a feedforward circuit in accordance with a preferred embodiment of the present invention.

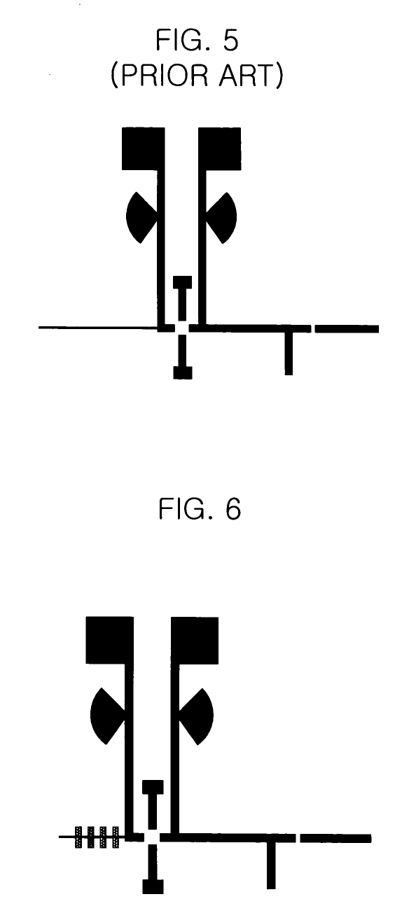

The voltage controlled oscillator of the present invention occupies less area comparing to a conventional voltage controlled oscillator shown in FIG. 5. That is, the voltage controlled oscillator of the present invention can be integrated more than the conventional voltage controlled oscillator.

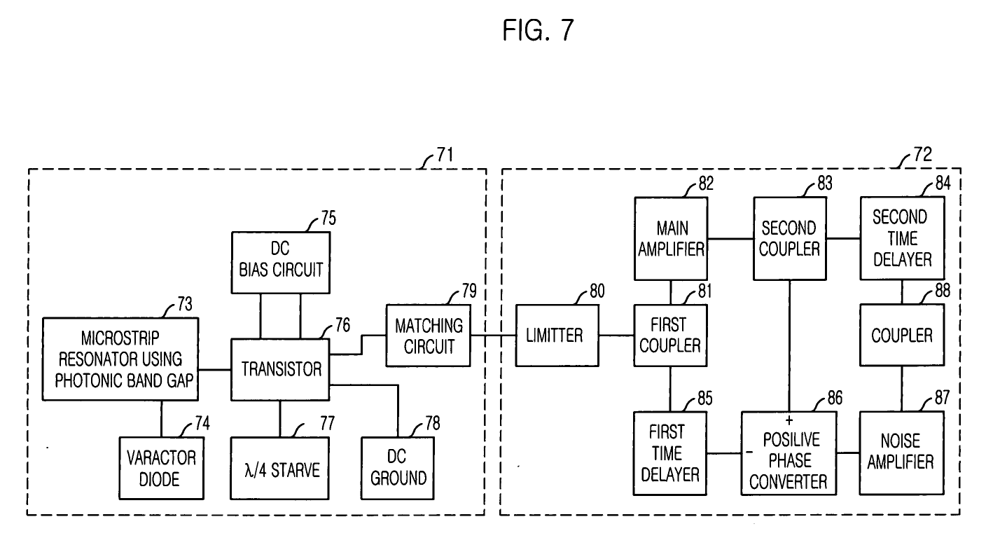

FIG. 7 is a diagram illustrating a voltage controlled oscillator using a photonic bandgap structure and a feedforward circuit in accordance with a preferred embodiment of the present invention.

Referring to FIG. 7, the voltage controlled oscillator of the present invention includes a resonation unit 71 and an oscillation unit 72. The resonation unit resonates an oscillated signal by using the resonator having the photonic bandgap structure, which has the transmission line, increasing the quality factor Q by maximizing coupling. The resonation unit 72 decrease phase noise of oscillated signal by controlling a size of phase of the oscillated signal with using the feedforward circuit.

At first, the resonation unit 71 includes a microstrip resonator having a photonic bandgap structure 73 for increasing the Q, factor, a varactor diode 74 for controlling resonate frequency by using an elements having variable characteristic according variation of applied voltage, a DC bias circuit 75 for generating a signal for outputting a resonate signal and operating a transistor 76, the transistor 76 for generating gain to signal having a specific frequency set by the varactor diode, a λ/4 stub 77 for controlling a state of open and short of the resonated signal, a DC ground 78 for connecting the transistor 76 to the ground and a matching circuit 79 for connecting to the limiter 80 by matching a phase and impedance of the oscillated signal to pre-set value.

Also, the resonation unit 72 includes a limiter 80 for preventing to receive a resonated signal bigger than a predetermined size, a first coupler 81 for receiving the resonated signal from the limiter 80 and copying a signal in order to generate a first copied signal, a main amplifier 82 for receiving the first copied signal and amplifying a the first copied signal in order to generate an amplified signal, a second coupler 83 for receiving the amplified signal and copying the amplified signal in order to generate a second copied signal, a first time delayer 85 for receiving the first copied signal and delaying the first copied signal as long as the first coped signal passes the main amplifier 82 and the second coupler 83 in order to generate a first time delayed signal, a positive phase converter 86 for receiving the first time delayed signal, reversing the first time delayed signal in order to generate a reversed signal, receiving the second copied signal from the second coupler 83 and combining the reversed signal and the second copied signal in order to generate a combined signal, an noise amplifier 87 for receiving the combined signal and amplifying the combined signal outputted from the phase converter 86 in order to generate a noise amplified signal, a second time delayer 84 for receiving the second copied signal and delaying the second copied signal outputted form the second coupler 83 as long as the second copied signal passes the phase converter 86 and the noise amplifier 87 in order to generate a second time delayed signal, and a coupler 88 for combining the noise amplified signal and the second time delayed signal.

In a meantime, operations of the voltage controlled oscillator of the present invention are explained in detail. The resonation unit 71 having the Q factor by using the photonic bandgap structure transmits an oscillated signal to the matching circuit 79. The matching circuit 79 controls the oscillated signal to have a reflected wave based on a condition of phase and impedance and transmits the controlled signal to the limiter 80 in the oscillation unit 72.

The limiter 80 limits to receive signals form the matching circuit 79 by amplitude of the signals. The signal passed through the limiter 80 becomes linearized and amplified by passing through the feedforward circuit.

As mentioned above, the present invention can reduce phase noise and increase efficiency of integration by using the photonic bandgap structure of a resonator and the feedforward circuit is used for maintaining high Q factor.

While the present invention has been described with respect to certain preferred embodiments, it will be apparent to those skilled in the art that various changes and modifications may be made without departing from the scope of the invention as defined in the following claims.

What is claimed is:

1. A voltage controlled oscillator using a resonator having a photonic bandgap structure and a feedforward circuit, the voltage controlled oscillator comprising:
resonation means for resonating an oscillated signal by using a resonator having the photonic bandgap structure in order to increase a quality factor; and
oscillation means for controlling a phase of the oscillated signal by using the feedforward circuit in order to reduce phase noise.

2. The voltage controlled oscillator as recited in claim 1, wherein the resonation means includes:
a microstrip resonator having a photonic bandgap structure for improving a quality factor;
a DC bias circuit for generating a signal for outputting an oscillated signal;
a transistor operated by the DC bias circuit for applying a gain to a signal having a specific frequency;
a varactor diode having a variable characteristic varied according to variation of voltage for controlling the resonate frequency;
a λ/4 stuve for controlling a state of open and short of the oscillated signal;
a DC ground for grounding the transistor; and
a matching circuit for connecting the oscillation mean and the limiter by matching a phase and impedance of the oscillated signal to a preset value.

3. The voltage controlled oscillator as recited in claim 1, wherein the oscillation means includes:
a limiter for preventing to receive a resonated signal bigger than a predetermined size;
a first coupler for receiving the resonated signal from the limiter and copying a signal in order to generate a first copied signal;
a main amplifier for receiving the first copied signal and amplifying a the first copied signal in order to generate an amplified signal;
a second coupler for receiving the amplified signal and copying the amplified signal in order to generate a second copied signal;
a first delayer for receiving the first copied signal and delaying the first copied signal as long as the first coped signal passes the main amplifier and the second coupler in order to generate a first time delayed signal;
a phase converter for receiving the first time delayed signal, reversing the first time delayed signal in order to generate a reversed signal, receiving the second copied signal from the second coupler and combining the reversed signal and the second copied signal in order to generate a combined signal;
an noise amplifier for receiving the combined signal and amplifying the combined signal outputted from the phase converter in order to generate a noise amplified signal;
a second time delayer for receiving the second copied signal and delaying the second copied signal outputted form the second coupler as long as the second copied signal passes the phase converter and the noise amplifier in order to generate a second time delayed signal; and
a coupler for combining the noise amplified signal and the second time delayed signal.

4. A method of operations of the voltage controlled oscillator by using a phonic bandgap structure and a feedforward circuit, the method comprising the steps of:
a) resonating an oscillated signal by using a resonator having the photonic bandgap structure in order to increase a quality factor; and
b) controlling a phase of the oscillated signal by using the feedforward circuit in order to reduce phase noise.
